(19) United States
(12) Patent Application Publication
(10) Pub. No.: US 2016/0295726 A1
(43) Pub. Date: Oct. 6, 2016

(54) Electronic Component and Robot Apparatus

(71) Applicant: Renesas Electronics Corporation, Tokyo (JP)

(72) Inventor: Yoichi Yoshida, Tokyo (JP)

(21) Appl. No.: 15/005,407

(22) Filed: Jan. 25, 2016

(30) Foreign Application Priority Data
Mar. 30, 2015 (JP) 2015-067880

(51) Int. Cl. H05K 5/02; B25J 17/00; B25J 19/00; H05K 7/14

(52) U.S. Cl. CPC H05K 5/0247; H05K 7/1427; H05K 5/0217; B25J 17/00; B25J 19/0029

(57) ABSTRACT

In a robot apparatus including a plurality of electronic components, it is possible to arbitrarily determine a coupling direction between the electronic components.

An electronic component includes a chassis having an aperture and a connector which is contained in the chassis and can be electrically coupled to the outside through the aperture. The connector has a structure that can rotate in the chassis around an axis in a normal direction of the aperture.

### CROSS-REFERENCE TO RELATED APPLICATIONS

The disclosure of Japanese Patent Application No. 2015-067880 filed on Mar. 30, 2015 including the specification, drawings and abstract is incorporated herein by reference in its entirety.

### BACKGROUND

The present invention relates to an electronic component and a robot apparatus, for example, relates to a robot apparatus formed when a user arbitrarily combines a plurality of electronic components.

For example, International Publication No. 2004/066132 discloses a structure in which a rotary type operation unit rotates based on a USB insertion port in an external electronic device including the USB insertion port and the rotary type operation unit coupled to the USB insertion port. Further, Japanese Unexamined Patent Application Publication No. 2014-75349 discloses a structure in which a rotary body rotates based on a main body in a power outlet including the main body provided with a power receptacle and the rotary body which is coupled to the main body through a rotary shaft member and which is provided with a USB insertion port.

### SUMMARY

In recent years, for example, an electronic hobby kit typified by electronic Lego blocks and the like is known. When the electronic hobby kit is used, a user can make a desired robot apparatus such as a vehicle by arbitrarily combining various module components such as a microcomputer, a sensor, and a motor. Here, in a general electronic hobby kit, electric wiring that couples between each module component is provided by, for example, two methods.

A first method is a method in which a cable that is separately provided outside couples between connectors fixedly provided to each module component. However, in this method, the cable is exposed outside the module components, so that an unfavorable situation for a user may occur, such as a situation in which the design of the robot apparatus is damaged.

A second method is a method in which connectors fixedly provided to each module component are formed into a shape to be able to directly couple to each other and the connectors are directly coupled. In this case, a method can be considered in which, for example, an exclusive wiring component including two connectors is prepared as one of the components and the module components are coupled through the exclusive wiring component. However, in the method as described above, a positional relationship of the module components is restricted according to a direction in which the connector is arranged, so that there is a risk that a degree of freedom to determine the entire shape of the robot apparatus is lowered. Further, there is a risk that a mechanical strength of the entire robot apparatus is lowered by a coupling portion between the connectors.

On the other hand, as a method to improve a degree of freedom to determine the positional relationship of the module components, for example, it is considered to apply methods of International Publication No. 2004/066132 and Japanese Unexamined Patent Application Publication No. 2014-75349. In the methods, it is possible to change a positional relationship between two components by providing a movable portion between the two components. However, when the components are mounted in the robot apparatus, a situation may occur in which an external force is applied to the movable portion, so that there is a risk that mechanical strength of the entire robot apparatus is not sufficiently secured.

The embodiments described later are made in view of the above situation, and other objects and novel features will become apparent from the description of the present specification and the accompanying drawings.

An electronic component according to an embodiment includes a chassis having an aperture and a connector which is contained in the chassis and can be electrically coupled to the outside through the aperture. The connector has a structure that can rotate in the chassis around an axis in a normal direction of the aperture.

According to the embodiment described above, in the robot apparatus including a plurality of electronic components, it is possible to arbitrarily determine a coupling direction between the electronic components.

### BRIEF DESCRIPTION OF THE DRAWINGS

FIGS. 1A and 1B are schematic diagrams showing an external form example of a robot apparatus according to a first embodiment of the present invention.

FIG. 2 is a block diagram showing a schematic configuration example of a control system of the robot apparatus of FIG. 1B.

FIGS. 3A and 3B are schematic diagrams showing a structure example of a structural unit of the robot apparatus of FIGS. 1A, 1B, and 2.

FIG. 4 is an illustration showing a situation in which a frame part in FIG. 3B is inserted into a junction part in FIG. 3A.

FIG. 5 is a schematic diagram showing a schematic external form example of an electronic component of the first embodiment of the present invention.

FIG. 6 is a schematic diagram showing a structure example around a rotary type connector in an electronic component according to a second embodiment of the present invention.

FIGS. 7A and 7B are schematic diagrams showing a structure example of an electronic component according to a third embodiment of the present invention.

FIGS. 8A and 8B are schematic diagrams showing a structure example of an electronic component according to a fourth embodiment of the present invention.

FIG. 9 is a schematic diagram showing a structure example of an electronic component according to a fifth embodiment of the present invention.

FIG. 10 is a schematic diagram showing a structure example of an electronic component according to a sixth embodiment of the present invention.

FIG. 11 is a schematic diagram showing a structure example of an electronic component according to a seventh embodiment of the present invention.

FIG. 12 is a schematic diagram showing a structure example of an electronic component according to an eighth embodiment of the present invention.

FIG. 13 is a diagram showing an external form of an external electronic device shown in International Publication No. 2004/066132.

### DETAILED DESCRIPTION

The following embodiments will be explained, divided into plural sections or embodiments, if necessary for convenience. Except for the case where it shows clearly in particular, they are not mutually unrelated and one has relationships such as a modification, details, and supplementary explanation of some or entire of another. In the following embodiments, when referring to the number of elements, etc. (including the number, a numeric value, an amount, a range, etc.), they may be not restricted to the specific number but may be greater or smaller than the specific number, except for the case where they are clearly specified in particular and where they are clearly restricted to a specific number theoretically.

Furthermore, in the following embodiments, it is needless to say that an element (including an element step etc.) is not necessarily indispensable, except for the case where it is clearly specified in particular and where it is considered to be clearly indispensable from a theoretical point of view, etc. Similarly, in the following embodiments, when shape, position relationship, etc. of an element etc. is referred to, what resembles or is similar to the shape substantially shall be included, except for the case where it is clearly specified in particular and where it is considered to be clearly not right from a theoretical point of view. This statement also applies to the numeric value and range described above.

A circuit element that forms each function block of the embodiment is not limited in particular. However, the circuit element is formed on a semiconductor substrate such as a single crystal silicon by a known integrated circuit technology of CMOS (complementary MOS transistor) or the like.

Hereinafter, the embodiments of the present invention will be described in detail with reference to the drawings. In all the drawings for explaining the embodiments, the same symbol is attached to the same member, as a principle, and the repeated explanation thereof will be omitted.

### First Embodiment

### Overview of Robot Apparatus

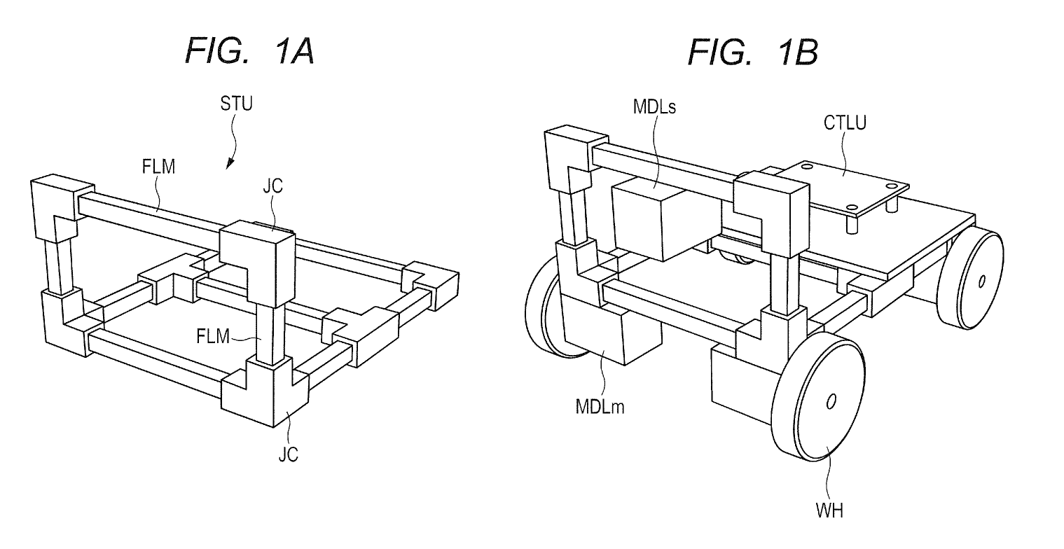

FIGS. 1A and 1B are schematic diagrams showing an external form example of a robot apparatus according to a first embodiment of the present invention. FIG. 1A shows a structural unit STU that forms a framework of the robot apparatus. Although the details will be described later, the structural unit STU includes a plurality of frame parts FLM that are electronic components and a plurality of junction parts JC that couples between the frame parts. A user or the like can construct the framework of the robot apparatus by arbitrarily combining the frame parts FLM and the junction parts JC.

FIG. 1B shows a vehicle apparatus which is an example of the robot apparatus. A user or the like can construct the robot apparatus as shown in FIG. 1B by arbitrarily attaching a control unit CTLU that is an electronic component and various controlled modules to the structural unit STU shown in FIG. 1A and further attaching various mechanical components as necessary. In an example shown in FIG. 1B, as the various controlled modules, a plurality of (for example, four) motor modules MDLm and a sensor module MDLs are attached.

In this example, the motor modules MDLm are respectively attached to the junction parts JC arranged at four corners of the structural unit STU. A wheel WH that is a mechanical component is attached to each of the motor modules MDLm and thereby four wheels of the vehicle apparatus are constructed. The sensor module MDLs is not limited in particular. However, the sensor module MDLs is a laser sensor or the like that senses an obstacle in front thereof and, for example, is attached to the frame part FLM arranged in a front portion of the structural unit STU. The control unit CTLU controls the motor modules MDLm (that is, progression of the vehicle apparatus) based on a detection result of the sensor module MDLs.

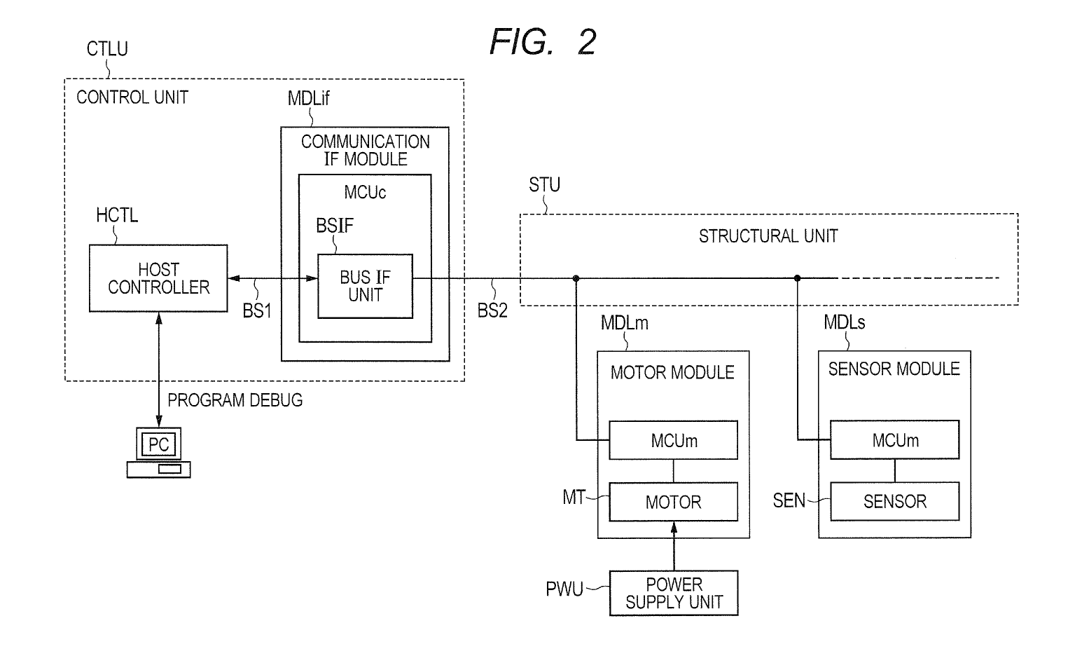

FIG. 2 is a block diagram showing a schematic configuration example of a control system of the robot apparatus of FIG. 1B. The control system shown in FIG. 2 includes the control unit CTLU, a plurality of controlled modules (here, the motor modules MDLm and the sensor module MDLs), and a bus BS2 that couples the control unit and the controlled modules. The control unit CTLU includes, for example, a host controller HCTL, a communication IF module MDLif, and a bus BS1 that couples them.

Although not limited in particular, the host controller HCTL consists of a widely used printed circuit board represented by, for example, an Arduino (registered trademark) circuit board and a Raspberry Pi (registered trademark) circuit board. The communication IF module MDLif consists of a printed circuit board on which a semiconductor device MCUc represented by, for example, a microcontroller and the like is mounted. The communication IF module MDLif is coupled to, for example, a terminal for the bus BS1 provided to the host controller HCTL and is integrated with the host controller HCTL. The bus BS1 is, for example, an SPI (Serial Peripheral Interface) bus or the like.

The semiconductor device (for example, a microcontroller) MCUc has a bus IF unit BSIF that mediates communication with the bus BS1 and communication with the bus BS2. The bus BS2 is a serial bus and is, for example, an I2C (Inter-Integrated Circuit) bus or the like. The I2C bus consists of four wirings including a power source voltage wiring, aground power source voltage wiring, a clock wiring, and a data wiring. Here, the bus BS2 is provided to the structural unit STU shown in FIG. 1A. Although the details will be described later, the structural unit STU forms an electrical power source path/communication path in the robot apparatus in addition to forming a mechanical framework of the robot apparatus.

The motor modules MDLm includes a control device MCUm represented by a microcontroller and the like and a motor MT. Similarly, the sensor module MDLs includes a control device MCUm and a sensor SEN. Although not shown in the drawings, the control device MCUm includes a serial interface that mediates communication with the bus (for example, the I2C bus) BS2. In this example, a power supply unit PWU for supplying power to the motor MT of the motor module MDLm is separately provided.

In FIG. 2, for example, a user or the like creates a control program executed by the host controller HCTL by using a personal computer PC or the like. The host controller HCTL appropriately issues a control instruction toward various controlled modules (here, the motor modules MDLm and the sensor module MDLs) based on the control program. The communication IF module MDLif receives a control instruction from the host controller HCTL, converts the control instruction into an instruction format for the bus (for example, the I2C bus) BS2, and thereafter transmits the converted control instruction to the bus BS2. The various controlled modules receive the control instruction from the host controller HCTL through the bus BS2 and perform processing according to the control instruction.

Although FIG. 2 shows a case in which one bus BS2 is included as an example, it is possible to include a plurality of buses. For example, when the number of controlled modules that are mounted in the robot apparatus is large and it is not possible for one bus BS2 to satisfy a predetermined control speed, it is possible to satisfy a request by providing a plurality of buses BS2. Alternatively, it is also beneficial to provide a plurality of buses BS2 according to a difference of control method of the controlled module. Specifically, for example, one bus BS2 is a bus for issuing a control instruction to a plurality of controlled modules by broadcast, and the other bus BS2 is a bus for individually issuing a control instruction for each controlled module

### Problem of Robot Apparatus

Here, for the robot apparatus as shown in FIGS. 1B and 2, the freedom to determine the entire shape of the robot apparatus, the mechanical strength of the robot apparatus, the designability of the robot apparatus, and the like are required. Specifically, first, it is possible to determine the framework of the robot apparatus at a high degree of freedom by using the structural unit STU as shown in FIG. LA. However, a problem may occur when determining the entire shape of the robot apparatus by combining various controlled modules to such a framework.

For example, in FIG. 1B, the sensor module MDLs is attached to a frame part FLM. Specifically, for example, a coupling portion for attaching the controlled module is provided at a predetermined position (here, on a lower surface) of the frame part FLM, and the sensor module MDLs is attached to the coupling portion. In this case, a user may assemble the structural unit STU of FIG. 1A so that the coupling portion is arranged on the lower surface of the frame part FLM, and thereafter the user may couple the sensor module MDLs to a cable-shaped bus BS2 whose one end is coupled to the control unit CTLU.

Here, in this case, the cable is exposed to the outside, so that the designability of the robot apparatus is degraded. Further, when there is a large number of controlled modules to be mounted, exposed cables are required to be drawn in a complicated manner, so that there is a risk that wiring mistake and the like of a user occur in addition to further degradation of designability. Therefore, it is beneficial that the bus BS2 is contained in the frame part FLM and the junction part JC. Specifically, for example, the bus BS2 is provided inside the frame part FLM and the junction part JC and a connector of the bus BS2 is provided at each end portion of the frame part FLM and the junction part JC. In this case, it is possible to mechanically and electrically couple the frame part FLM and the junction part JC by inserting the frame part FLM into the junction part JC.

However, in this case, an attaching direction of the sensor module MDLs is restricted depending on a direction of the connector. In other words, normally, the insertion direction of the connector is fixed. Therefore, in the example described above, when inserting the frame part FLM to which the sensor module MDLs is attached into the junction part JC, for example, it is possible to insert the frame part FLM in a direction in which a coupling portion is arranged on a lower surface. However, it is difficult to insert the frame part FLM in a direction in which the coupling portion is arranged on an upper surface, a front surface, or a rear surface. As a result, the degree of freedom to determine the entire shape of the robot apparatus is lowered.

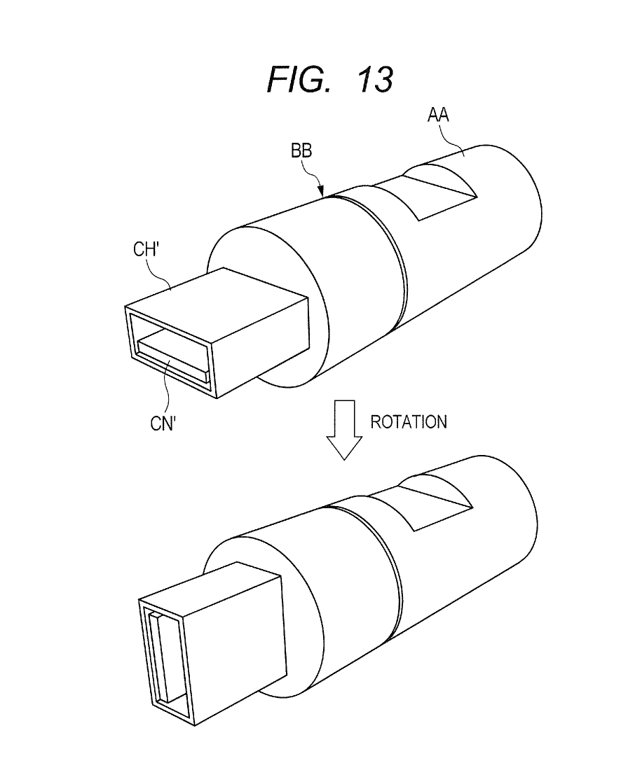

Therefore, for example, it is considered to apply the methods as described in International Publication No. 2004/066132 and Japanese Unexamined Patent Application Publication No. 2014-75349 described above. FIG. 13 is a diagram showing an external form of an external electronic device shown in International Publication No. 2004/066132. In FIG. 13, it is possible to rotate the direction of the connector CN′ with respect to the rotary type operation unit AA through the movable portion BB. When providing a frame part having a structure coupled through the movable portion BB by applying such a method, it is possible to change the attaching direction of the sensor module MDLs. However, in this case, a mechanical strength at the movable portion BB is insufficient and, for example, a problem occurs in which the sensor module MDLs swings with respect to the framework.

### Details of Structural Unit

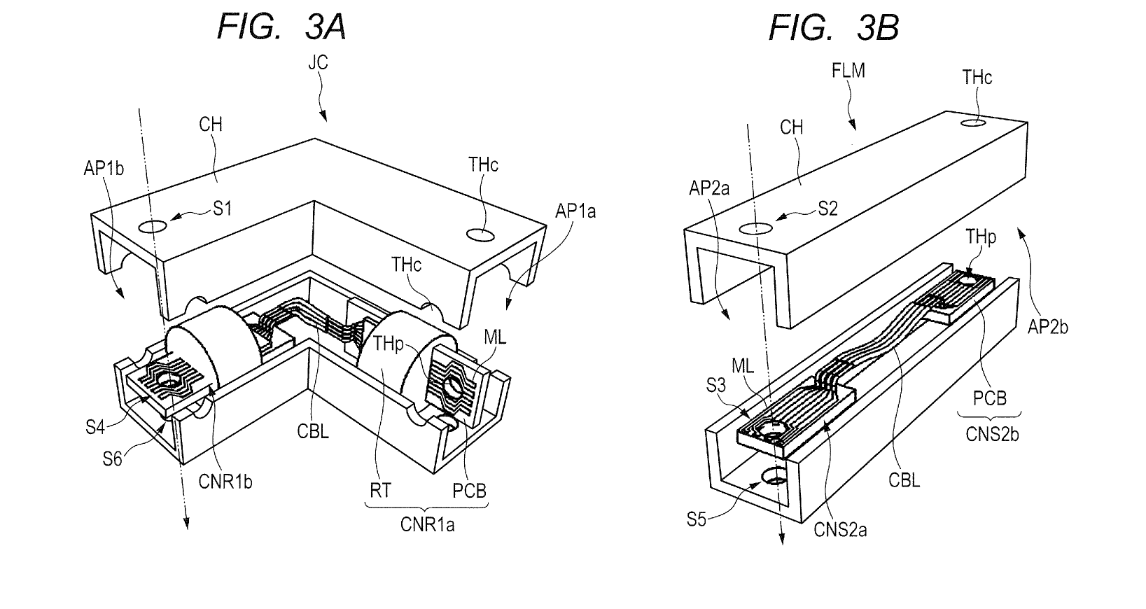

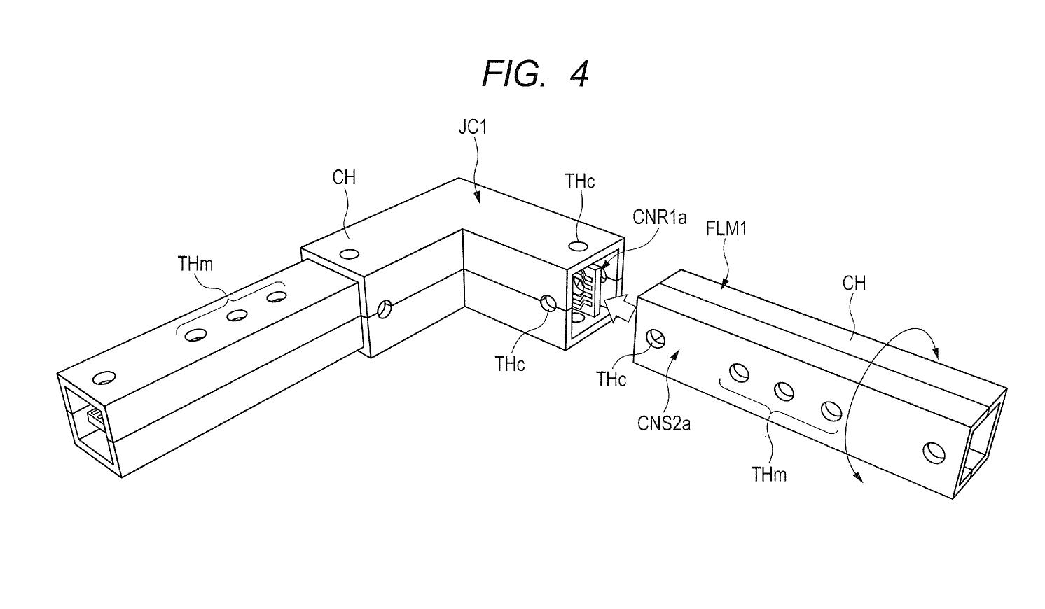

FIGS. 3A and 3B are schematic diagrams showing a structure example of a structural unit of the robot apparatus of FIGS. 1A, 1B, and 2. FIG. 3A shows a structure example of a junction part (electronic component) JC in the structural unit STU. FIG. 3B shows a structure example of a frame part (electronic component) FLM in the structural unit STU. FIG. 4 is an illustration showing a situation in which the frame part in FIG. 3B is inserted into the junction part in FIG. 3A.

The junction part JC shown in FIG. 3A includes a chassis (a first chassis) CH having two apertures AP1a and AP1b, rotary type connectors CNR1a and CNR1b contained in the chassis CH, and a cable CBL. The rotary type connector (a first A connector) CNR1a can be electrically coupled to the outside through the aperture (a first A aperture) AP1a and the rotary type connector (a first B connector) CNR1b can be electrically coupled to the outside through the aperture (a first B aperture) AP1b. The cable CBL forms the bus BS2 shown in FIG. 2 and couples the rotary type connector CNR1a and the rotary type connector CNR1b in the chassis CH.

Here, the rotary type connector CNR1a has a structure that can rotate in the chassis CH around an axis in a normal direction of the aperture (the first A aperture) AP1a. Similarly, the rotary type connector CNR1b has a structure that can rotate in the chassis CH around an axis in a normal direction of the aperture (the first B aperture) AP1b. As an example of the above, each of the rotary type connectors CNR1a and CNR1b in FIG. 3A has a cylindrical shape and includes a rotary member RT having a structure that can rotate in a circumferential direction of the cylindrical shape and a printed circuit board PCB on which metal wiring (wiring layer) ML for electrically coupling with the outside is formed. Here, a set of four metal wirings ML and a set of four cables CBL are used as in the example of I2C bus.

For example, the rotary member RT of the rotary type connector CNR1a is contained in the chassis CH so that a direction of its rotary axis corresponds to a normal direction of the aperture AP1a. The printed circuit board PCB is integrally attached to the rotary member RT. Thereby, an installation angle of the printed circuit board PCB when seeing the aperture AP1a from the outside (in other words, an angle of insertion of the connector from the outside) can be appropriately changed by the rotation of the rotary member RT. The cable CBL is twisted according to the rotation of the rotary type connector CNR1a or CNR1b, so that the cable CBL has an enough length that allows variation in an expansion direction caused by the twist.

On the other hand, the frame part FLM shown in FIG. 3B includes a chassis (a second chassis) CH having two apertures (second apertures) AP2a and AP2b, stationary type connectors (second connectors) CNS2a and CNS2b contained in the chassis CH, and a cable CBL. The stationary type connector CNS2a can be electrically coupled to the outside through the aperture AP2a and the stationary type connector CNS2b can be electrically coupled to the outside through the aperture AP2b. The cable CBL forms the bus BS2 shown in FIG. 2 and couples the stationary type connector CNS2a and the stationary type connector CNS2b in the chassis CH.

Here, each of the stationary type connectors CNS2a and CNS2b includes the printed circuit board PCB in the same manner as in FIG. 3A. However, different from the case of FIG. 3A, each of the stationary type connectors CNS2a and CNS2b does not include the rotary member RT and is fixed to the chassis CH even though not shown in FIG. 3B. Therefore, for example, an installation angle of the printed circuit board PCB when seeing the aperture AP2a from the outside (in other words, an angle of insertion of the connector from the outside) is fixed.

FIG. 4 shows a situation in which the frame part FLM1 as shown in FIG. 3B is attached to the junction part JC1 as shown in FIG. 3A. In this example, module mounting tapped holes THm are provided to a predetermined surface of the frame part FLM1 and the sensor module MDLs as shown in FIG. 1B is attached to the tapped holes. Although not shown in FIG. 4, the frame part FLM1 is separately provided with an electrical coupling portion for coupling the internal bus BS2 to the sensor module MDLs.

As shown in FIG. 3A, the junction part JC1 is provided with the rotary type connector CNR1a and, as shown in FIG. 3B, the frame part FLM1 is provided with the stationary type connector CNS2a. The chassis (a first chassis) CH of the junction part JC1 has a structure that can be mechanically coupled to the chassis (a second chassis) CH of the frame part FLM1 in a direction in which the apertures (for example, both surfaces have a square shape) of both chassis face each other. In this example, the chassis of the junction part JC1 has the aperture having an area to which the chassis of the frame part FLM1 can be inserted. In this case, it is possible to insert the frame part FLM1 into the junction part JC1 so that a part of the frame part FLM1 is enclosed by the junction part JC1. As a result, it is possible to secure a mechanical strength in an insertion portion.

In this example, the electrical coupling between the frame part FLM1 and the junction part JC1 is achieved by contacting the metal wirings ML on the printed circuit board PCB in the junction part JC in FIG. 3A with the metal wirings ML on the printed circuit board PCB in the frame part FLM in FIG. 3B. In this case, it is necessary to adjust installation angles of each printed circuit board PCB (that is, the rotary type connector CNR1a and the stationary type connector CNS2a) so that the metal wirings ML of both printed circuit boards PCB are in contact with each other.

Under these circumstances, in the example of FIG. 4, the rotary type connector CNR1a is provided to the junction part JC1. The rotary type connector (the first A connector) CNR1a of the junction part JC1 has a structure that can rotate in the chassis CH around an axis in a normal direction of the aperture so as to fit the shape of the stationary type connector (the second connector) CNS2a of the frame part FLM1. As a result, it is possible to insert the frame part FLM1 into the junction part JC1 so that the module mounting tapped holes THm face any direction (in this example, direction for every 90°). In the example of FIG. 1B, it is possible to attach the sensor module MDLs to any one of the lower surface, the upper surface, the front surface, and the rear surface of the frame part FLM.

Further, in FIGS. 3A, 3B, and 4, one of four tapped holes (first tapped holes) THc is provided for every 90° to the chassis CH of the junction part JC. One tapped hole (a second tapped hole) THp is provided to the printed circuit board PCB of the junction part JC. A linear jig (for example, a screw) can penetrate two tapped holes THc facing each other among the four tapped holes THc and the tapped hole THp in the printed circuit board PCB.

On the other hand, one of two tapped holes THc is provided for every 180° to the chassis CH of the frame part FLM. One tapped hole THp is provided to the printed circuit board PCB of the frame part FLM. A linear jig (for example, a screw) can penetrate the two tapped holes THc and the tapped hole THp in the printed circuit board PCB.

In the case of such a configuration, as shown in FIG. 4, after inserting the frame part FLM1 into the junction part JC1 at a predetermined installation angle, it is possible to fasten the two parts with a screw or the like through the tapped holes. For example, as shown in FIGS. 3A and 3B, it is possible to fasten the two parts with a screw or the like in order from the chassis of the junction part (step S1) to the chassis of the frame part (step S2) to the printed circuit board of the frame part (step S3) to the printed circuit board of the junction part (step S4) to the chassis of the frame part (step S5) to the chassis of the junction part (step S6).

Thereby, it is possible to further increase the mechanical strength of a coupling portion between the frame part FLM1 and the junction part JC1. Specifically, it is possible to prevent a positional shift or the like between the two chassis CH and further it is possible to maintain a good contact state between the connectors of the two chassis CH. However, it is not limited to the screwing method as described above. For example, the positional shift or the like may be prevented by only inserting the chassis of the frame part into the chassis of the junction part. Further, for example, it is possible to maintain a good contact state between the connectors by forming the shapes of the connectors into recessed and protruded shapes as used in USB or the like.

### Typical Effects of First Embodiment

When using the first embodiment as described above, typically, in the robot apparatus including a plurality of electronic components, it is possible to arbitrarily determine a coupling direction between the electronic components. More specifically, it is possible to freely determine the entire shape of the robot apparatus while sufficiently securing the mechanical strength and designability of the robot apparatus. As a result, for example, it is possible to improve convenience of a user and the like.

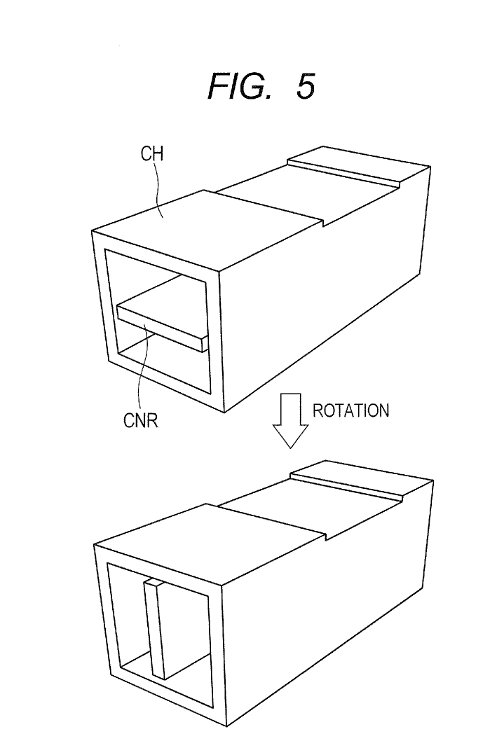

Here, a difference from the configuration of FIG. 13 described above will be described. FIG. 5 is a schematic diagram showing a schematic external form example of an electronic component of the first embodiment of the present invention. In the electronic component shown in FIG. 5, the rotary type connector CNR is contained in the chassis CH and the rotary type connector CNR has a structure that can rotate in the chassis CH. On the other hand, the configuration shown in FIG. 13 has a structure in which the chassis CH itself shown in FIG. 5 can be twisted. Further, when the USB insertion port CH′ in FIG. 13 is considered as a chassis that contains the connector CN′ in FIG. 13, the connector CN′ has a structure that cannot rotate in the chassis.

Here, the apertures of the chassis CH of the frame part FLM and the junction part JC have a square shape. However, it is not limited to this, and the apertures may have, for example, a circular shape or the like. In this case, for example, in the same manner as in the case of FIG. 3A, when the tapped hole is provided for every 45° in the chassis, it is possible to insert the frame part FLM into the junction part JC for every 45° of installation angle. As a result, it is possible to change the installation angle of the controlled module for every 45°.

### Second Embodiment

### Shape of Rotary Type Connector

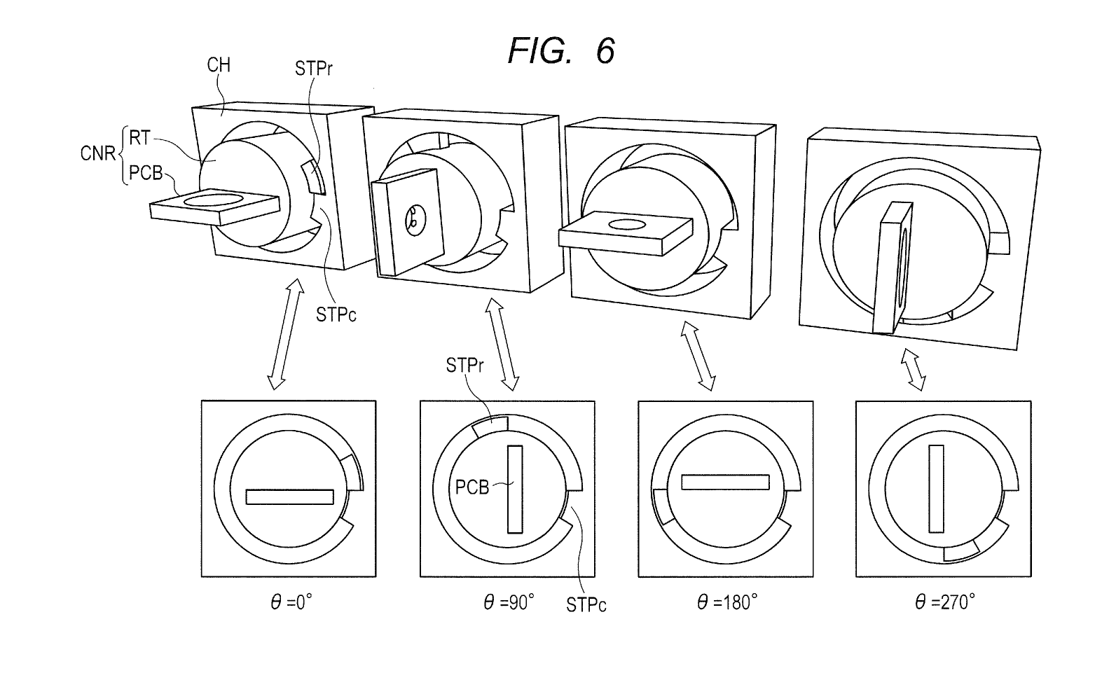

FIG. 6 is a schematic diagram showing a structure example around a rotary type connector in an electronic component according to a second embodiment of the present invention. As described in the first embodiment, the rotary type connector CNR can rotate in the chassis CH. However, for example, when the rotary type connector CNR rotates more than 360° and rotates two times or three times, there is a risk that the cable CBL is twisted excessively and damaged. Therefore, for example, it is beneficial to use the rotary type connector CNR as shown in FIG. 6.

In the example of FIG. 6, a projection-shaped stopper STPr is provided to the outer circumference of the rotary member RT and a projection-shaped stopper STPc is provided to the inner circumference of the chassis CH. For example, when the installation angle of the rotary type connector CNR is 0°, the stoppers STPr and STPc are in contact with each other in a gap between the rotary member RT and the chassis CH. In this case, when the rotary type connector CNR is rotated, the stoppers STPr and STPc come into contact with each other before the installation angle of the rotary type connector reaches 360°, and thereby the rotation is stopped. From this state, when the rotary type connector CNR is rotated in the opposite direction, the stoppers STPr and STPc come into contact with each other when the installation angle of the rotary type connector reaches 0°, and thereby the rotation is stopped.

In this way, by providing the stoppers STPr and STPc, it is possible to limit the rotation range of the rotary member RT, so that it is possible to prevent the cable CBL from being damaged. As a result, it is possible to secure a mechanical strength of the electronic component.

### Third Embodiment

### Shape of Rotary Type Connector or Stationary Type Connector

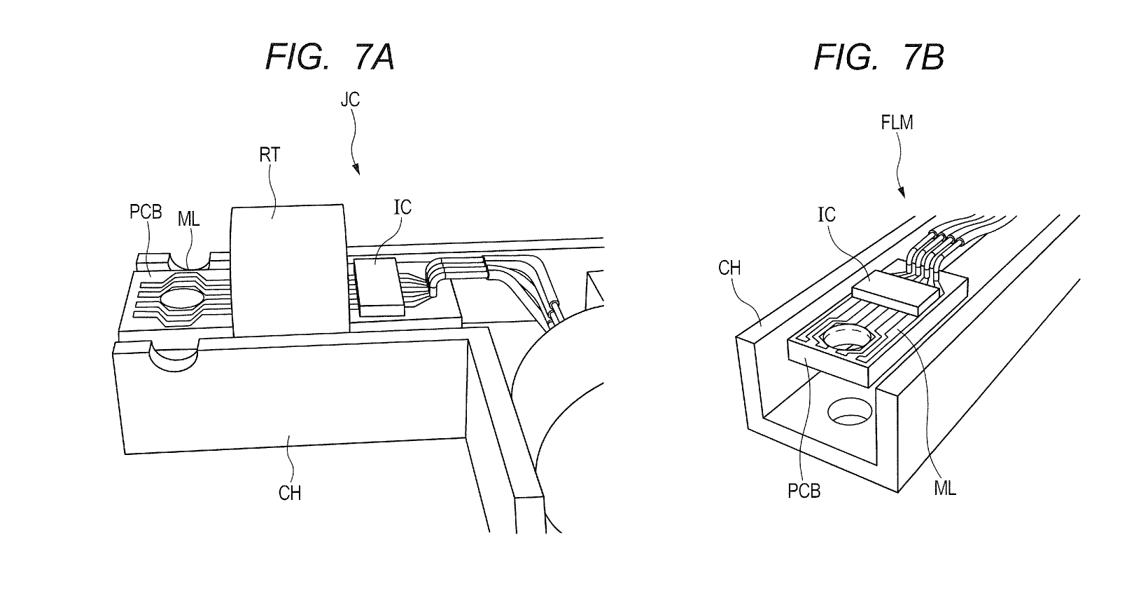

FIGS. 7A and 7B are schematic diagrams showing a structure example of an electronic component according to a third embodiment of the present invention. FIG. 7A shows a structure example around the rotary type connector of the junction part JC shown in FIG. 3A. FIG. 7B shows a structure example around the stationary type connector of the frame part FLM shown in FIG. 3B. The connectors shown in FIGS. 7A and 7B are different from the configuration examples of FIGS. 3A and 3B in a point that a semiconductor device IC is mounted on the printed circuit board PCB. The semiconductor device IC is coupled to the metal wirings (wiring layer) ML on the printed circuit board PCB.

Examples of the semiconductor device IC include a noise filter, a repeater (that is, a bidirectional buffer), and a microcomputer. For example, when the motor module MDLm as shown in FIG. 1B is coupled to the bus BS2, there is a risk that noise on the bus BS2 increases. Further, when the length of the bus BS2 is long, there is a risk that the amount of signal on the bus decreases. In such cases, it is possible to improve the reliability of bus communication by mounting the semiconductor device IC such as a noise filter and a repeater on the printed circuit board PCB.

When the semiconductor device IC such as a microcomputer is mounted on the printed circuit board PCB, it is possible to transmit predetermined information to the host controller HCTL, so that it is possible to construct a robot apparatus having higher functions. Specifically, for example, it is possible to transmit information of the electronic component, which is stored in advance, to the host controller HCTL through the bus BS2, or it is possible to transmit the inclination of the connector of the electronic component to the host controller HCTL by using a microcomputer including a sensor. The semiconductor device IC need not be mounted on all of the printed circuit boards PCB, but may be mounted on some of the printed circuit boards PCB.

### Fourth Embodiment

### Shape of Rotary Type Connector or Stationary Type Connector

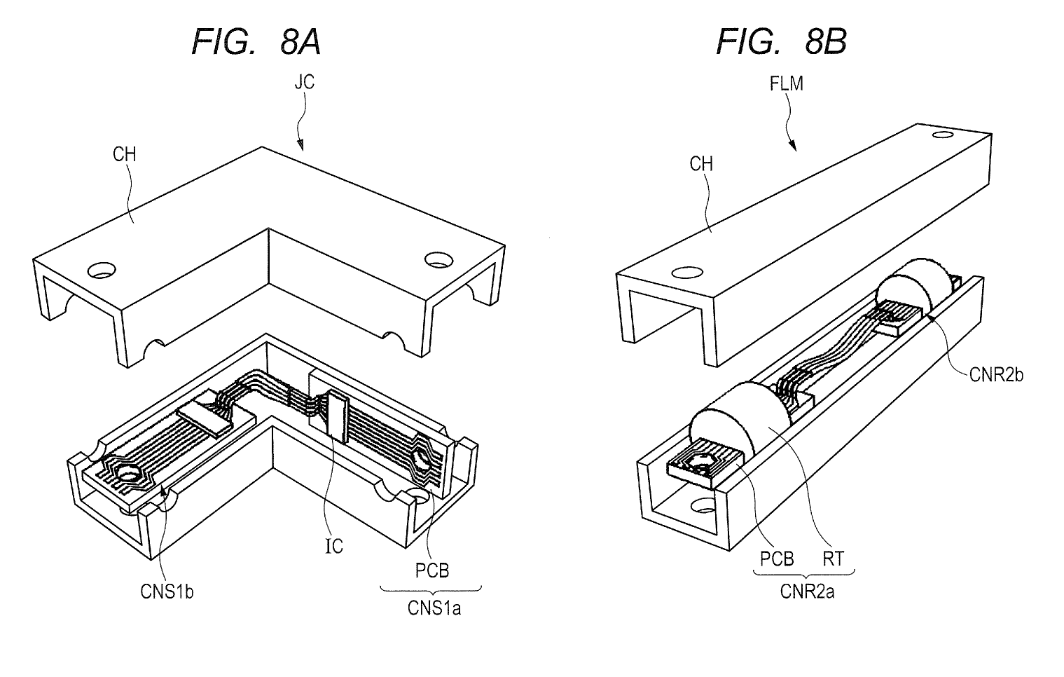

FIGS. 8A and 8B are schematic diagrams showing a structure example of an electronic component according to a fourth embodiment of the present invention. The junction part JC and the frame part FLM shown in FIGS. 8A and 8B are different from the configuration examples shown in FIGS. 3A and 3B in a point that the rotary type connectors and the stationary type connectors are exchanged.

Specifically, different from the case of FIG. 3A, the junction part JC shown in FIG. 8A includes stationary type connectors (second connectors) CNS1a and CNS1b, and different from the case of FIG. 3B, the frame part FLM shown in FIG. 8B includes rotary type connectors (first A connector and first B connector) CNR2a and CNR2b. In this way, when at least one of the junction part JC and the frame part FLM includes the rotary type connectors, it is possible to obtain the effects as described in the first embodiment.

### Fifth Embodiment

### Structure of Junction Part

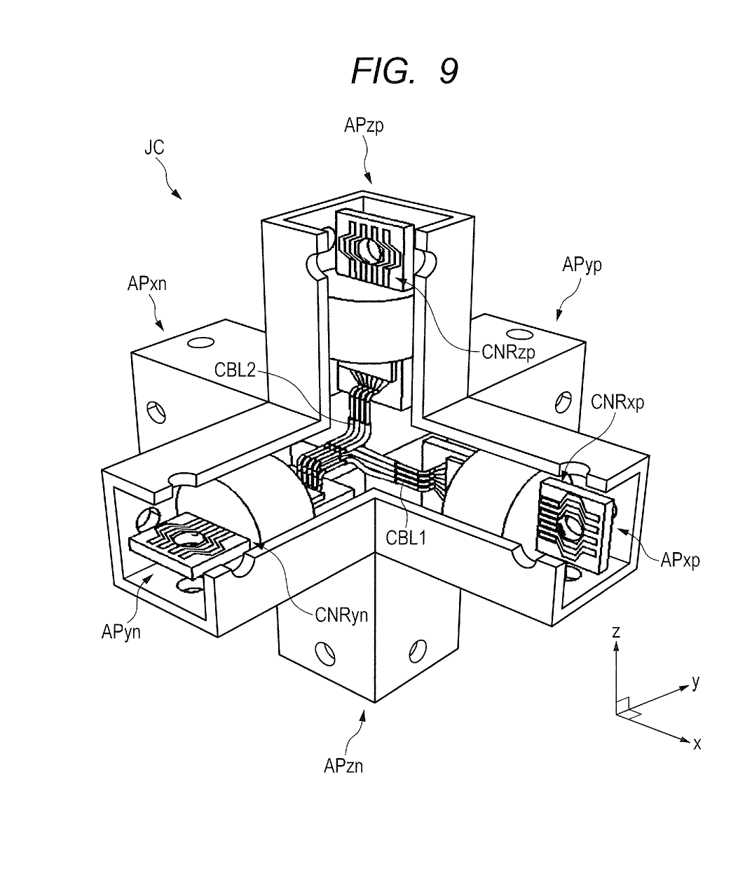

FIG. 9 is a schematic diagram showing a structure example of an electronic component according to a fifth embodiment of the present invention. FIG. 9 shows a junction part JC having six apertures APxp, APxn, APyp, APyn, APzp, and APzn. A normal direction of the aperture APxp corresponds to a plus direction of the x axis and a normal direction of the aperture APxn corresponds to a minus direction of the x axis. Similarly, normal directions of the apertures APyp and APyn correspond to a plus direction and a minus direction of the y axis, respectively, and normal directions of the apertures APzp and APzn correspond to a plus direction and a minus direction of the z axis, respectively. The x axis, the y axis, and the z axis are perpendicular to each other.

In the same manner as in FIG. 3A, the rotary type connectors are respectively provided near the six apertures APxp, APxn, APyp, APyn, APzp, and APzn. For example, in FIG. 9, the rotary type connector (a first A connector) CNRxp can be electrically coupled to the outside through the aperture (a first A aperture). Further, the rotary type connector (a first B connector) CNRyn can be electrically coupled to the outside through the aperture (a first B aperture) APyn and the rotary type connector (a first C connector) CNRzp can be electrically coupled to the outside through the aperture (a first C aperture) APzp. Although not shown in FIG. 9, the same goes for the other apertures.

The rotary type connector (the first A connector) CNRxp and the rotary type connector (the first B connector) CNRyn are coupled by a cable (a first cable) CBL1. Further, the rotary type connector (the first B connector) CNRyn and the rotary type connector (the first C connector) CNRzp are coupled by a cable (a second cable) CBL2. In the same manner, each rotary type connector is serially coupled through a cable. The order of the coupling is not particularly limited. In other words, for example, six rotary type connectors that are serially coupled in advance at regular intervals through cables may be provided, and the six rotary type connectors may be appropriately arranged at six apertures, respectively.

By using such a junction parts JC, when defining three axes perpendicular to each other (x, y, and z axes) as rotary axes, it is possible to insert the frame part FLM at any installation angle (for example, at every 90°) from both the plus direction and the minus direction of the three axes. As a result, it is possible to further improve the degree of freedom to determine the entire shape of the robot apparatus, so that it is possible to improve user's convenience.

The coupling method of the six rotary type connectors is not necessarily limited to the serial coupling as described above, and it is possible to use a method in which the six rotary type connectors are coupled in common in some form. For example, depending on conditions, it is possible to use a method in which one rotary type connector is used as a base and the other rotary type connectors are coupled in a tree shape. However, in this case, the rotary type connector used as a base has five branch points, so that there are a risk that the structure is complicated, a risk that damage maybe caused by a twist when the rotary type connector is rotated, and a risk that the electrical characteristics of the bus BS2 are degraded. From this viewpoint, it is desirable to use the method of FIG. 6.

Here, the junction part JC is described which corresponds to six directions including a plus direction and a minus direction of three axes. However, in the same manner, it is possible to provide a junction part JC which corresponds to three or more directions of the six directions. By the way, a junction part JC which corresponds to two directions of the six directions has a configuration as shown in FIG. 3A or a configuration where the shape of the chassis CH in FIG. 3A is changed to a linear shape.

Further, here, six rotary type connectors are coupled to one bus BS2. However, for example, it is possible to employ a configuration in which two buses BS2 are provided as described in FIG. 2 and three rotary type connectors are coupled to each bus. In this case, in the same manner as in FIG. 9, simply, two sets of three rotary type connectors that are serially coupled are provided, and a total of six rotary type connectors may be appropriately arranged to six apertures, respectively.

### Sixth Embodiment

### Shape of Rotary Type Connector or Stationary Type Connector

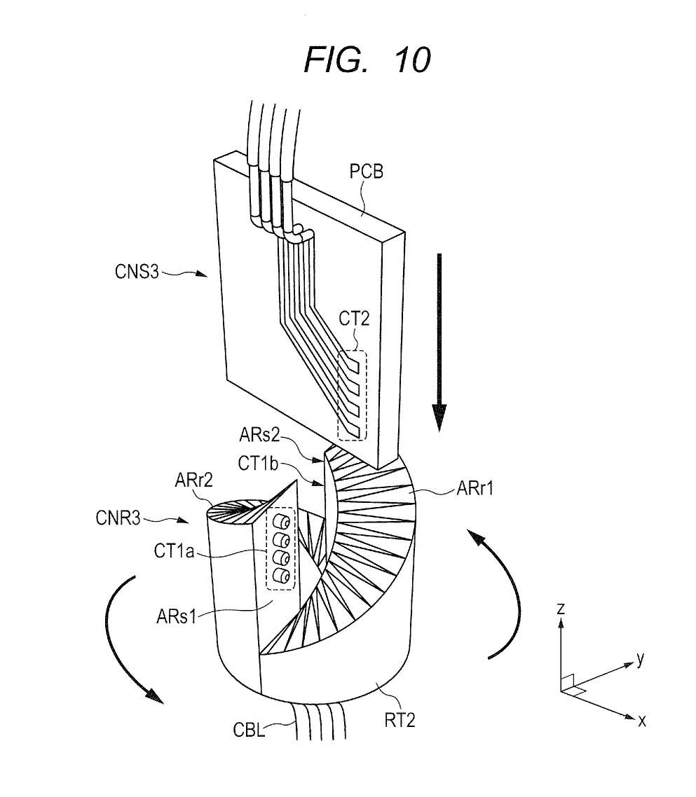

FIG. 10 is a schematic diagram showing a structure example of an electronic component according to a sixth embodiment of the present invention. FIG. 10 shows a situation in which a stationary type connector CNS3 is inserted into a rotary type connector CNR3. As shown in the first and the fourth embodiments, one of the rotary type connector CNR3 and the stationary type connector CNS3 is contained in the junction part JC and the other is contained in the frame part FLM.

The rotary type connector CNR3 includes a rotary member (a first member) RT2 whose shape is different from that in the case of FIG. 3A and a contact portion (a first contact portion) CT1a. The rotary member RT2 has a shape obtained by processing a ring surface of a cylindrical member into a helical shape along a circumferential direction, and a cut surface ARs1 along a direction of a rotary axis (here, the z axis) of the cylindrical member is formed at an end portion of the ring surface ARr1 of the helical shape.

The contact portion CT1a is provided on the cut surface ARs1 of the rotary member RT2. Here, the contact portion CT1a is composed of four metal terminals arranged in parallel in the z direction. In the same manner as the case of the cylindrical rotary member RT shown in FIG. 3A, the rotary member RT2 as described above is contained in the chassis CH not shown in FIG. 10 so that the direction of the rotary axis of the cylindrical member corresponds to a normal direction of the aperture of the chassis CH.

On the other hand, the stationary type connector CNS3 has a printed circuit board (a second member) PCB where a contact portion (a second contact portion) CT2 is provided. The contact portion CT2 includes four metal terminals that are arranged in parallel in the z direction so as to fit the contact portion CT1a of the rotary type connector CNR3. For example, the four metal terminals are formed from regions of end portions of the four metal wirings ML shown in FIG. 3A.

Here, a case is assumed in which the rotary type connector CNR3 and the stationary type connector CNS3 are coupled together. Specifically, a case is assumed in which the stationary type connector CNS3 is inserted into the rotary type connector CNR3 in the z direction. In this case, as shown in FIG. 10, the printed circuit board (the second member) PCB moves along the helically-shaped ring surface ARr1, so that the rotary member (the first member) RT2 rotates until the contact portion CT1a and the contact portion CT2 are coupled together.

As a result, in the example of FIG. 10, as long as the installation angle of the rotary type connector CNR3 when the stationary type connector CNS3 is inserted into the rotary type connector CNR3 is in a range from 0° to 180° (that is, as long as the printed circuit board PCB is in contact with the ring surface ARr1), it is possible to electrically couple both connectors together by only an insertion operation in the z direction. In other words, for example, in the case of FIG. 4 described above, the insertion operation has to be performed after a user or the like manually adjusts the installation angle of the rotary type connector CNR1a to some extent. However, in the example of FIG. 10, such a manual adjustment is not required. As a result, it is possible to improve convenience of a user.

Further, in the example of FIG. 10, corresponding to a case in which the installation angle of the rotary type connector CNR3 is in a range from 180° to 360°, the rotary member (the first member) RT2 has a ring surface (a first B ring surface) ARr2 and a cut surface (a first B cut surface) ARs2, which are similar to the ring surface (a first A ring surface) ARr1 and the cut surface (a first A cut surface) ARs1 described above. The ring surface ARr2 is formed by processing a ring surface into a helical shape from the cut surface ARs1 in the same manner as the ring surface ARr1. The cut surface ARs2 is formed at an end portion of the ring surface ARr2.

A contact portion (a first B contact portion) CT1b is provided on the cut surface ARs2. The contact portion CT1b is electrically coupled to the contact portion (a first A contact portion) CT1a on the cut surface ARs1. Thereby, even when the installation angle of the rotary type connector CNR3 is in a range from 180° to 360° (in other words, regardless of the installation angle of the rotary type connector CNR3), it is possible to electrically couple the stationary type connector CNS3 and the rotary type connector CNR3 by only an insertion operation in the z direction.

Here, a configuration example is described in which one of the two helically-shaped ring surfaces is provided for every 180°. However, it is not particularly limited to this. For example, similarly, one of four helically-shaped ring surfaces may be provided for every 90°, or one helically-shaped ring surface may be provided in a range of 360°. Depending on the number of the helically-shaped ring surfaces to be formed, the degree of inclination of the ring surface (that is, easiness of coupling between connectors) and the amount of twist of the cable CBL caused by one insertion operation vary, so that the number of the helically-shaped ring surfaces to be formed may be appropriately determined so that the degree of inclination and the amount of twist are appropriate.

In the example of FIG. 10, the rotary member RT2 rotates up to 180° in the same direction (here, counterclockwise) at all times every time one insertion operation is performed. Therefore, every time the insertion operation is performed, there is a risk that the twist of the cable CBL is accumulated, so that it is desirable to provide the stoppers STPr and STPc as shown in FIG. 6.

### Seventh Embodiment

### Structure of Controlled Module

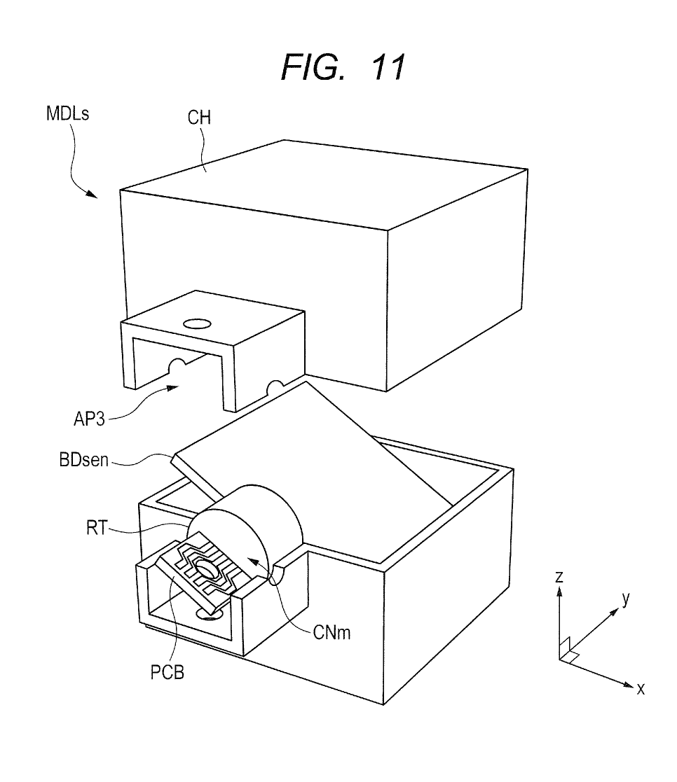

FIG. 11 is a schematic diagram showing a structure example of an electronic component according to a seventh embodiment of the present invention. In the example of FIG. 11, a structure example of the sensor module MDLs, which is one of electronic components, is shown. While a mechanical and electrical coupling method between the junction part JC and the frame part FLM is described in the above embodiments, the same method can be applied to a controlled module.

The sensor module MDLs shown in FIG. 11 includes a chassis CH, a module connector CNm contained in the chassis CH, and a sensor substrate BDsen. The module connector CNm can be electrically coupled to the outside through an aperture AP3. In the example of FIG. 11, in the same manner as in FIG. 3A, the module connector CNm is composed of a rotary type connector including a rotary member RT and a printed circuit board PCB. The sensor substrate BDsen is mechanically coupled to the module connector CNm. On the sensor substrate BDsen, as shown in FIG. 2, the control device MCUm and a predetermined sensor SEN are mounted.

Here, for example, a case is assumed in which the sensor module MDLs in FIG. 11 is coupled to the aperture APyp of the junction part JC in FIG. 9, and a combination method of a connector structure of the sensor module MDLs and a connector structure of the junction part JC will be described. As the combination method, the following three methods are considered.

First, a case is considered in which the connector of the sensor module MDLs is a rotary type connector as shown in FIG. 11 and the connector of the junction part JC is a stationary type connector as shown in FIG. 8a. In this case, the installation angle of the sensor substrate BDsen is limited according to the installation angle of the stationary type connector of the junction part JC. However, it is possible to arbitrarily determine the installation angle of the chassis CH of the sensor module MDLs (in the example of FIG. 11, for every 90° by using the y axis as the rotary axis).

Second, a case is considered in which the connector of the sensor module MDLs is a stationary type connector as shown in FIG. 3B and the connector of the junction part JC is a rotary type connector as shown in FIG. 9. In this case, it is possible to arbitrarily determine the installation angle of the sensor substrate BDsen (for example, for every 90° by using the y axis as the rotary axis). However, the installation angle of the chassis CH of the sensor module MDLs is limited according to the installation angle of the sensor substrate BDsen.

Third, a case is considered in which the connector of the sensor module MDLs is a rotary type connector as shown in FIG. 11 and the connector of the junction part JC is also a rotary type connector as shown in FIG. 9. In this case, it is possible to arbitrarily determine the installation angle of the sensor substrate BDsen (for example, for every 90° by using the y axis as the rotary axis). Further, it is possible to arbitrarily determine the installation angle of the chassis CH of the sensor module MDLs with respect to the installation angle of the sensor substrate BDsen (for example, for every 90° by using the y axis as the rotary axis).

For example, the installation angle of the sensor substrate BDsen and the like may be important. Further, the installation angle of the chassis CH of the sensor module MDLs maybe required to be determined from a viewpoint of designability and a positional relationship when further attaching some sort of component to the chassis CH in the same manner as in FIG. 4. From this perspective, the three methods described above can raise the degree of freedom as needed, so that it is possible to improve user's convenience. In particular, the third method has the highest degree of freedom. However, from a viewpoint of cost, the first and the second methods are beneficial.

Here, a case is assumed in which the installation angle of the sensor substrate BDsen is determined and thereafter the sensor substrate BDsen is fixedly used at the determined installation angle in a robot apparatus. However, depending on conditions, it is possible to realize a mechanism in which the installation angle of the sensor substrate BDsen is dynamically changed in the chassis of the sensor module MDLs in the robot apparatus by applying the third method described above.

### Eighth Embodiment

Structure of Frame part or Junction Part

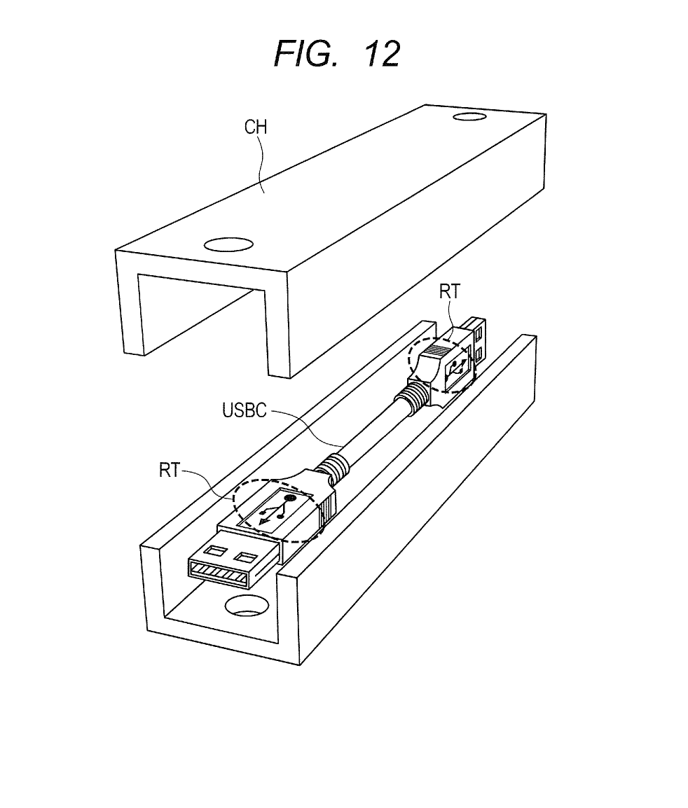

FIG. 12 is a schematic diagram showing a structure example of an electronic component according to an eighth embodiment of the present invention. In the embodiments described above, a case in which the I2C bus is applied to the bus BS2 is described as an example. However, it is not limited to this, and various serial buses can be applied. As an example, FIG. 12 shows a structure example of the frame part or the junction part when a USB bus is applied to the bus BS2.

In the example of FIG. 12, a widely used USB cable USBC is contained in the chassis CH. Although details are omitted, for example, a rotary member RT having the same shape as that in FIG. 3A is attached to connector portions at both ends of the USB cable USBC. Also by using such a configuration, it is possible to obtain the same effects as those of the first embodiment.

In the USB, a tree-shaped topology is used, so that it is required to provide a hub at a branch point. In this case, for example, in the same manner as in the case of FIGS. 7A and 7B, a USB connector portion may be formed of a printed circuit board, and the hub may be formed of a semiconductor device mounted on the printed circuit board. However, when the hub is required at the branch point as described above, there is a risk that the cost of the entire robot apparatus increases, and further, depending on conditions, there is a risk that the number of the controlled modules that can be mounted in the robot apparatus is restricted and the mounting position of the controlled module is restricted due to a positional relationship with the hub. Therefore, from this viewpoint, it is beneficial to apply a serial bus such as the I2C bus.

While the invention made by the inventors has been specifically described based on the embodiments, the present invention is not limited to the embodiments and may be variously modified without departing from the scope of the invention. For example, the above embodiments are described in detail in order to describe the present invention in an easily understandable manner, and the embodiments are not necessarily limited to those that include all the components described above. Further, some components of a certain embodiment can be replaced by components of another embodiment, and components of a certain embodiment can be added to components of another embodiment. Further, regarding some components of each embodiment, it is possible to perform addition/deletion/exchange of other components.

What is claimed is:

1. An electronic component comprising:
a chassis including a first A aperture; and
a first A connector which is contained in the chassis and which can be electrically coupled to outside through the first A aperture,
wherein the first A connector has a structure that can rotate in the chassis around an axis in a normal direction of the first A aperture.

2. The electronic component according to claim 1,
wherein the chassis further includes a first B aperture,
wherein the electronic component further includes
a first B connector which is contained in the chassis and which can be electrically coupled to the outside through the first B aperture, and
a cable that couples the first A connector and the first B connector together in the chassis,
wherein the first B connector has a structure that can rotate in the chassis around an axis in a normal direction of the first B aperture, and
wherein the cable is twisted according to rotation of the first A connector or the first B connector and has an enough length that allows variation in an expansion direction caused by the twist.

3. The electronic component according to claim 2,
wherein the chassis further includes a first C aperture,
wherein the electronic component further includes a first C connector which is contained in the chassis and which can be electrically coupled to the outside through the first C aperture,
wherein the first C connector has a structure that can rotate in the chassis around an axis in a normal direction of the first C aperture, and
wherein the cable includes
a first cable that couples the first A connector and the first B connector together, and
a second cable that couples the first B connector and the first C connector together.

4. The electronic component according to claim 3,
wherein the axis in the normal direction of the first A aperture, the axis in the normal direction of the first B aperture, and the axis in the normal direction of the first C aperture are perpendicular to each other.

5. The electronic component according to claim 1,
wherein the first A connector includes
a rotary member having a shape that can rotate in the chassis around an axis in the normal direction of the first A aperture, and
a printed circuit board which is attached to the rotary member and on which a wiring layer to electrically couple to the outside is formed.

6. The electronic component according to claim 5,
wherein the rotary member has a cylindrical shape.

7. The electronic component according to claim 5,
wherein the rotary member and the chassis are provided with a stopper that limits a rotation range of the rotary member.

8. The electronic component according to claim 5,
wherein a semiconductor device coupled to the wiring layer is mounted on the printed circuit board.

9. The electronic component according to claim 5,
wherein one of four first tapped holes is provided to the chassis for every 90°,
wherein a second tapped hole is provided to the printed circuit board, and
wherein a linear jig can penetrate two first tapped holes facing each other among the four first tapped holes and the second tapped hole.

10. The electronic component according to claim 2,
wherein the cable forms a serial bus.

11. The electronic component according to claim 1,
wherein the electronic component is used as one component of a robot apparatus that can be assembled by a user.

12. A robot apparatus that can be formed when a user combines a plurality of electronic components,
wherein a first electronic component, which is one of the electronic components, includes
a first chassis including a first A aperture, and
a first A connector which is contained in the first chassis and which can be electrically coupled to outside through the first A aperture,
wherein a second electronic component, which is another one of the electronic components, includes
a second chassis including a second aperture, and
a second connector which is contained in the second chassis and which can be electrically coupled to the outside through the second aperture,
wherein the first chassis has a structure in which the first chassis can be mechanically coupled to the second chassis in a direction in which the first A aperture and the second aperture face each other, and
wherein the first A connector has a structure that can rotate in the first chassis around an axis in a normal direction of the first A aperture so as to fit a shape of the second connector.

13. The robot apparatus according to claim 12,
wherein the first chassis further includes a first B aperture,
wherein the first electronic component further includes a first B connector which is contained in the first chassis and which can be electrically coupled to the outside through the first B aperture, and
a cable that couples the first A connector and the first B connector in the first chassis,
wherein the first B connector has a structure that can rotate in the first chassis around an axis in a normal direction of the first B aperture, and
the cable is twisted according to rotation of the first A connector or the first B connector and has an enough length that allows variation in an expansion direction caused by the twist.

14. The robot apparatus according to claim 12,
wherein the first A connector includes
a rotary member having a shape that can rotate in the first chassis around an axis in the normal direction of the first A aperture, and
a printed circuit board which is attached to the rotary member and on which a wiring layer to electrically couple to the outside is formed.

15. The robot apparatus according to claim 14,
wherein the rotary member has a cylindrical shape.

16. The robot apparatus according to claim 14,
wherein the rotary member and the first chassis are provided with a stopper that limits a rotation range of the rotary member.

17. The robot apparatus according to claim 14,
wherein a semiconductor device coupled to the wiring layer is mounted on the printed circuit board.

18. The robot apparatus according to claim 13,
wherein the cable forms a serial bus.

19. The robot apparatus according to claim 12,
wherein the first A connector includes
a first member having a shape obtained by processing a ring surface of a cylindrical member into a helical shape along a circumferential direction, a cut surface along a direction of a rotary axis of the cylindrical member being formed at an end portion of the ring surface of the helical shape, the first member being contained in the first chassis so that the direction of the rotary axis of the cylindrical member corresponds to the normal direction of the first A aperture, and
a first contact portion provided on the cut surface,
wherein the second connector includes a second member where a second contact portion is provided, and
wherein when the first A connector and the second A connector are coupled together, the second member moves along the ring surface of the helical shape, so that the first member rotates until the first contact portion and the second contact portion are coupled together.

20. The robot apparatus according to claim 19,
wherein the first member includes
a helically-shaped first A ring surface formed by processing the ring surface into a helical shape in a predetermined angle range smaller than 360°,
a first A cut surface formed at an end portion of the first A ring surface,
a helically-shaped first B ring surface formed by processing the ring surface into a helical shape in the predetermined angle range from the first A cut surface, and
a first B cut surface formed at an end portion of the first B ring surface, and
wherein the first A connector includes
a first A contact portion provided on the first A cut surface, and
a first B contact portion which is provided on the first B cut surface and is electrically coupled to the first A contact portion.
